(19) United States
(12) Patent Application Publication
(10) Pub. No.: US 2025/0254952 A1
(43) Pub. Date: Aug. 7, 2025

(54) POWER TRANSISTOR AND METHOD FOR PRODUCING A POWER TRANSISTOR

(71) Applicant: Robert Bosch GmbH, Stuttgart (DE)

(72) Inventor: Jens Baringhaus, Sindelfingen (DE)

(21) Appl. No.: 19/044,095

(22) Filed: Feb. 3, 2025

(30) Foreign Application Priority Data
Feb. 7, 2024 (DE) 10 2024 201 073.1

(51) Int. Cl. H10D 62/85; H01L 21/02; H10D 62/80; H10D 62/832

(52) U.S. Cl. CPC H10D 62/8503; H01L 21/0254; H01L 21/02565; H10D 62/8325; H10D 62/875

(57) ABSTRACT

A power transistor. The power transistor has a monocrystalline SiC layer. An AlGaN layer is arranged on the monocrystalline SiC layer. A gallium oxide layer is arranged on the AlGaN layer.

### FIELD

The present invention relates to a power transistor and to a method for producing a power transistor.

### BACKGROUND INFORMATION

Power transistors based on gallium oxide have a lower on-resistance than comparable power transistors based on SiC or GaN.

However, gallium oxide has a low thermal conductivity, and therefore polycrystalline SiC substrates on which a gallium oxide layer is deposited are used for the production of vertical gallium oxide transistors. This is usually carried out using a gallium oxide donor substrate.

Disadvantages include that this procedure is expensive, the gallium oxide donor substrate has a smaller diameter than commercially available polycrystalline SiC substrates, and the transition between SiC and gallium oxide has a high electrical resistance.

An object of the present invention is to overcome these disadvantages.

### SUMMARY

A power transistor has a monocrystalline SiC layer. According to an example embodiment of the present invention, an AlGaN layer is arranged on the monocrystalline SiC layer, wherein a gallium oxide layer is arranged on the AlGaN layer.

An advantage here is that the conduction band of AlGaN is between the conduction bands of SiC and gallium oxide, and therefore the electrical resistance between SiC and gallium oxide is low.

In a development of the present invention, the AlGaN layer has an aluminum-to-gallium ratio of 1:4-1:2.

An advantage here is that the energetic barrier to the gallium oxide and to the SiC can be adjusted by varying the Al concentration in the AlGaN layer.

In a further example embodiment of the present invention, an Al concentration of the AlGaN layer decreases toward the gallium oxide layer.

An advantage here is that the electrical resistance between SiC and gallium oxide is further reduced since the band gap and thus the energetic position of the conduction band edge changes gradually. The energetic transition is thus continuous and not abrupt.

In a development of the present invention, the gallium oxide layer in a region facing the AlGaN layer has an n-dopant concentration greater than 5e18 cm\hat{ }−3.

An advantage here is that the energetic barrier between the AlGaN and the gallium oxide can be further reduced by the high doping in order to ensure low-loss current flow.

In a further example embodiment of the present invention, a GaN layer is arranged between the AlGaN layer and the gallium oxide layer.

An advantage here is that the conduction band of GaN is between the conduction bands of AlGaN and gallium oxide, and therefore the electrical resistance between SiC and gallium oxide is very low.

In a development of the present invention, the AlGaN layer has a first dopant gradient, wherein the first dopant gradient decreases toward the gallium oxide layer from a side of the AlGaN layer facing the SiC layer.

An advantage here is that the energetic barrier of the AlGaN to GaN is lower than the energetic barrier of the AlGaN to SiC. Due to the higher dopant concentration on the side facing the SiC, the energetic barrier can be reduced in order to provide a homogeneous barrier on both sides.

In a further example embodiment of the present invention, the GaN layer has a second dopant gradient, wherein the second dopant gradient increases toward the gallium oxide layer from a side of the GaN layer facing the AlGaN layer.

An advantage here is that the energetic barrier of the GaN to AlGaN is lower than the energetic barrier of the GaN to gallium oxide. As a result of the increased dopant concentration on the side facing the gallium oxide, the energetic barrier can be reduced in order to provide a homogeneous barrier on both sides. In a development of the present invention, the gallium oxide layer has a third dopant gradient, wherein a doping of the gallium oxide layer is greatest in a lower region facing the SiC layer.

A method according to an example embodiment of the present invention for producing a power transistor comprises depositing an AlGaN layer on a monocrystalline SiC layer by means of MOCVD and depositing a gallium oxide layer on the AlGaN layer by means of MOCVD or HVPE.

In a development of the present invention, a GaN layer is deposited on the AlGaN layer by means of MOCVD.

Further advantages can be found in the following description of exemplary embodiments and in the rest of the disclosure herein.

### BRIEF DESCRIPTION OF THE DRAWINGS

The present invention is explained below with reference to preferred embodiments and the figures.

FIG. 1 shows a first exemplary embodiment of the power transistor according to the present invention.

FIG. 2 shows a second exemplary embodiment of the power transistor according to the present invention.

FIG. 3 shows a method for producing a power transistor, according to an example embodiment of the present invention.

### DETAILED DESCRIPTION OF EXAMPLE EMBODIMENTS

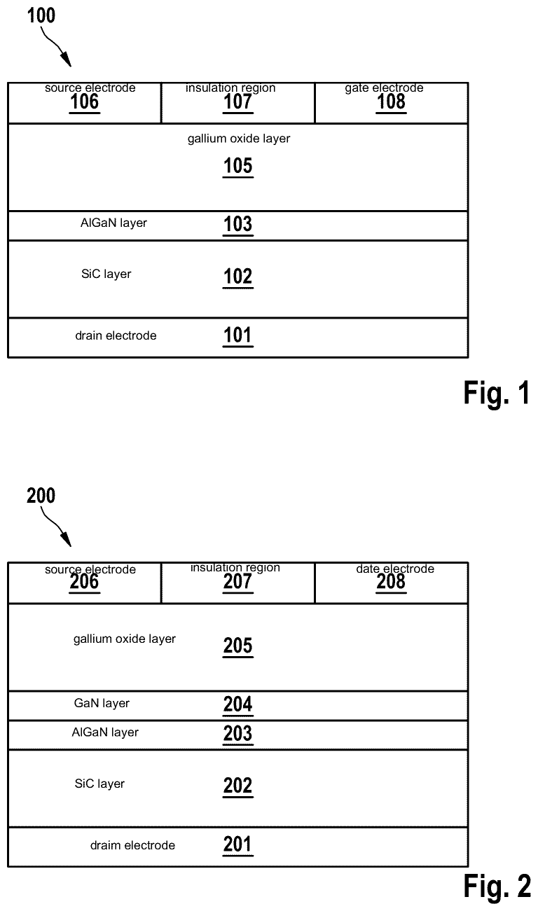

FIG. 1 shows a first exemplary embodiment of the power transistor 100 according to the present invention. The power transistor 100 comprises a monocrystalline SiC layer 102. An AlGaN layer 103 is arranged on the SiC layer 102. A gallium oxide layer 105 is arranged on the AlGaN layer 103. In order to reduce a resistance at the transition between the AlGaN layer 103 and the gallium oxide layer 105, the gallium oxide layer 105 can optionally have a very high n-dopant concentration, in particular greater than 5e18 cm\hat{ }−3, in the lower region, i.e., directly above the AlGaN layer 103.

FIG. 2 shows a second exemplary embodiment of the power transistor 200 according to the present invention. The power transistor 200 comprises a monocrystalline SiC layer 202. An AlGaN layer 203 is arranged on the SiC layer 202. A GaN layer 204 is arranged on the AlGaN layer 203. A gallium oxide layer 205 is arranged on the GaN layer 203. The GaN layer 203 has a layer thickness of 50-200 nm. The dopant concentration of the GaN layer 204 is greater than 1e19 cm\hat{ }−3. The doping can be homogeneous or can have a dopant gradient that increases upward from the side of the GaN layer 204 facing the AlGaN layer 203.

The monocrystalline SiC layer 102 and 202 has an n-dopant concentration greater than 5e18 cm\hat{ }−3. The AlGaN layer 103 and 203 has a layer thickness of at least 50 nm. The Al-to-Ga concentration in the AlGaN layer 103 and 203 preferably has a ratio of 1:4-1:2. Ideally, the Al concentration is chosen such that the energetic barriers to the SiC and to the gallium oxide are the same. The aim is to create an energetic transition from SiC to the gallium oxide that makes low-loss current transport possible. The dopant concentration of the AlGaN layer 103 and 203 is greater than 5e18 cm\hat{ }−3, preferably 1e20 cm\hat{ }−3. The doping can be homogeneous or can have a dopant gradient that decreases upward from the side of the AlGaN layer 103 and 203 facing the SiC layer 102 and 202. This means that the conduction band edge corresponds as closely as possible to that of the gallium oxide on the side facing the gallium oxide and corresponds as closely as possible to the conduction band edge of the SiC on the side facing the SiC. The power transistors 100 and 200 each comprise a source electrode 106 and 206, respectively, and a gate electrode 108 and 208, respectively, which are arranged on the gallium oxide layer 104 and 204, respectively. The source electrodes 106 and 206 and the gate electrodes 108 and 208 are electrically separated from each other via an insulation region 107 and 207, respectively. Drain electrodes 101 and 201 are arranged below the silicon layer 102 and 202, respectively.

The present invention is applicable, for example, in power transistors, in particular MOSFETs or JFETs, which are used in electric drive trains of electric or hybrid vehicles, for example in DC/DC converters and inverters, as well as in vehicle chargers. The power transistors can also be used in inverters for household appliances such as washing machines.

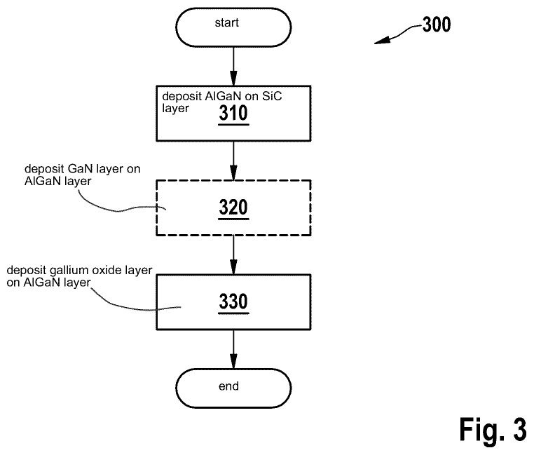

FIG. 3 shows a method 300 for producing a power transistor. The method starts with a step 310 in which an AlGaN layer is deposited on a monocrystalline SiC layer, preferably by means of MOCVD. The AlGaN layer has a dopant concentration greater than 5e18 cm\hat{ }−3, preferably greater than 1e20 cm\hat{ }−3. The AlGaN layer can have a first dopant gradient, wherein the first dopant gradient is largest directly above the monocrystalline SiC layer and decreases as the AlGaN layer thickness increases, i.e., the dopant concentration of the AlGaN layer has a value of 1le20 cm\hat{ }−3 directly above the SiC layer and reduces to 5e18 cm\hat{ }−3 as the layer thickness of the AlGaN layer increases. In a following step 330, a gallium oxide layer is deposited on the AlGaN layer by means of MOCVD or HVPE. The gallium oxide layer can also have a dopant gradient, wherein the doping preferably has an n-dopant concentration greater than 5e18 cm\hat{ }−3 in the lower region, i.e., the region facing the AlGaN layer. In the following steps (not shown), the power transistor is completed by suitable processing of the gallium oxide layer, also called device layer, and applying the electrical contacts and insulating them according to the related art.

Optionally, in a step 320 performed between steps 310 and 330, a GaN layer may be deposited on the AlGaN layer by means of MOCVD. The GaN layer has a dopant concentration greater than 5e18 cm\hat{ }−3, preferably greater than 1e20 cm\hat{ }−3. The GaN layer can have a second dopant gradient, wherein the second dopant gradient is smallest directly above the AlGaN layer and increases as the AlGaN layer thickness increases, i.e., the dopant concentration of the GaN layer has a value of 5e18 cm\hat{ }−3 directly above the AlGaN layer and increases to a value of le20 cm\hat{ }−3 as the layer thickness of the AlGaN layer increases.

1-10. (canceled)

11. A power transistor, comprising:
a monocrystalline SiC layer;
an AlGaN layer arranged on the monocrystalline SiC layer; and
a gallium oxide layer arranged on the AlGaN layer.

12. The power transistor according to claim 11, wherein the AlGaN layer has an aluminum-to-gallium ratio of 1:4-1:2.

13. The power transistor according to claim 12, wherein an Al concentration of the AlGaN layer decreases toward the gallium oxide layer.

14. The power transistor according to claim 11, wherein the gallium oxide layer has an n-dopant concentration greater than 5e18 cm\hat{ }−3 in a region facing the AlGaN layer.

15. The power transistor according to claim 11, wherein a GaN layer is arranged between the AlGaN layer and the gallium oxide layer.

16. The power transistor according to claim 11, wherein the AlGaN layer has a first dopant gradient, wherein the first dopant gradient decreases toward the gallium oxide layer from a side of the AlGaN layer facing the SiC layer.

17. The power transistor according to claim 16, wherein the GaN layer has a second dopant gradient, wherein the second dopant gradient increases toward the gallium oxide layer from a side of the GaN layer facing the AlGaN layer.

18. The power transistor according to claim 17, wherein the gallium oxide layer has a third dopant gradient, wherein a doping of the gallium oxide layer is greatest in a lower region facing the SiC layer.

19. A method for producing a power transistor, comprising the following steps:
depositing an AlGaN layer on a monocrystalline SiC layer using MOCVD; and
depositing a gallium oxide layer on the AlGaN layer by using MOCVD or HVPE.

20. The method according to claim 19, wherein a GaN layer is deposited on the AlGaN layer using MOCVD.
